(19) United States
(12) Patent Application Publication
(10) Pub. No.: US 2024/0361519 A1
(43) Pub. Date: Oct. 31, 2024

(54) OPTICAL RECEIVER

(71) Applicant: Mitsubishi Electric Corporation, Tokyo (JP)

(72) Inventors: Mizuki SHIRAO, Tokyo (JP); Ryota TAKEMURA, Tokyo (JP); Junichi SUZUKI, Tokyo (JP); Nobuo OHATA, Tokyo (JP)

(73) Assignee: Mitsubishi Electric Corporation, Tokyo (JP)

(21) Appl. No.: 18/763,651

(22) Filed: Jul. 3, 2024

Related U.S. Application Data
(63) Continuation of application No. PCT/JP2022/007062, filed on Feb. 22, 2022.

(51) Int. Cl. G02B 6/12; H01L 31/0232; H01L 31/0304; H01L 31/105

(52) U.S. Cl. CPC G02B 6/12002; H01L 31/02325; H01L 31/03046; H01L 31/105

(57) ABSTRACT

An optical receiver includes: a support base; a waveguide-type light receiving element fixed to a surface of the support base; and an optical circuit element fixed to the surface of the support base, wherein the waveguide-type light receiving element includes: a semi-insulating semiconductor substrate; a light absorbing layer formed on one main surface of the semiconductor substrate and has a pair of joint surfaces perpendicular to the one main surface of the semiconductor substrate and an incident end face on which light is incident and which has facing end sides of the joint surfaces as a pair of opposite sides, the incident end face having a layer thickness longer than a layer width; an n-type semiconductor layer joined to one of the joint surfaces of the light absorbing layer, and a p-type semiconductor layer joined to the other of the joint surfaces of the light absorbing layer.

### CROSS REFERENCE TO RELATED APPLICATIONS

This application is a Continuation of PCT International Application No. PCT/JP2022/007062, filed on Feb. 22, 2022, all of which is hereby expressly incorporated by reference into the present application.

### TECHNICAL FIELD

The present disclosure relates to an optical receiver.

### BACKGROUND ART

In fields of optical communication, optical information processing, and the like, a compound semiconductor light receiving element has been put into practical use as a high-sensitivity light receiver.

As a semiconductor light receiving element for optical communication, a waveguide-type semiconductor light receiving element on which signal light is incident from a direction horizontal to a light absorbing layer is known.

A waveguide-type semiconductor light receiving element is disclosed in Patent Literature 1.

The waveguide-type semiconductor light receiving element disclosed in Patent Literature 1 is a waveguide-type semiconductor light receiving element in which an n⁺-InP buffer layer, an n⁺-InGaAsP intermediate refractive index layer, an n-InGaAs light absorbing layer, a p⁺-InGaAsP band discontinuous relaxation layer, a p⁺-InP cladding layer, and a p⁺-InGaAs contact layer are sequentially laminated on a semi-insulating InP substrate 1.

### CITATION LIST

### Patent Literature

Patent Literature 1: JP 11-68127 A

### SUMMARY OF INVENTION

### Technical Problem

In the waveguide-type semiconductor light receiving element disclosed in Patent Literature 1, intermediate refractive index layers are formed on and under a light absorbing layer having a thin layer thickness in order to obtain high coupling tolerance with respect to a positional deviation of an incident light spot.

However, in the waveguide-type semiconductor light receiving element disclosed in Patent Literature 1, in a case where the light absorbing layer of the waveguide-type semiconductor light receiving element is butt-joint joined to an optical waveguide in an optical circuit element having an optical waveguide formed of a silicon (Si) layer, there arises a problem that the light absorbing layer causes coupling loss due to mode mismatch with respect to the optical waveguide and does not contribute to relaxation of coupling tolerance between the light absorbing layer and the optical waveguide.

The present disclosure has been made in view of the above point, and an object of the present disclosure is to obtain a waveguide-type light receiving element capable of not only relaxing coupling tolerance in a case of butt-joint joining to an optical waveguide having a large mode diameter, for example, an optical fiber or a planar lightwave circuit (PLC), but also relaxing coupling tolerance even in a case of butt-joint joining to an optical waveguide formed of a silicon layer in an optical circuit element.

### Solution to Problem

An optical receiver according to the present disclosure comprises: a support base; a waveguide-type light receiving element fixed to a surface of the support base; and an optical circuit element fixed to the surface of the support base, wherein the waveguide-type light receiving element includes: a semi-insulating semiconductor substrate; a light absorbing layer that is formed on one main surface of the semiconductor substrate and has a pair of joint surfaces perpendicular to the one main surface of the semiconductor substrate and an incident end face on which light is incident and which has facing end sides of the pair of joint surfaces as a pair of opposite sides, the incident end face having a layer thickness longer than a layer width; an n-type semiconductor layer joined to one of the pair of joint surfaces of the light absorbing layer on the one main surface of the semiconductor substrate; and a p-type semiconductor layer joined to the other of the pair of joint surfaces of the light absorbing layer on the one main surface of the semiconductor substrate, and the optical circuit element includes an optical waveguide having an emitting end face to emit light, the emitting end face facing the incident end face of the light absorbing layer in the waveguide-type light receiving element.

### Advantageous Effects of Invention

According to the present disclosure, an n-type semiconductor layer and a p-type semiconductor layer are disposed on one main surface of a semiconductor substrate with a light absorbing layer interposed therebetween in a lateral direction with respect to the one main surface of the semiconductor substrate, and an incident end face of the light absorbing layer has a layer thickness longer than a layer width. Therefore, coupling tolerance can be relaxed even in a case of butt-joint joining to an optical waveguide formed of a silicon layer in an optical circuit element.

### BRIEF DESCRIPTION OF DRAWINGS

FIG. 1 is an end view illustrating a waveguide-type light receiving element according to a first embodiment.

FIG. 2 is a top view illustrating a waveguide-type light receiving element according to a second embodiment.

FIG. 3 is a cross-sectional view cut along A-A in FIG. 2.

FIG. 4 is a cross-sectional view cut along B-B in FIG. 2.

FIG. 5 is a perspective view illustrating an optical receiver according to a third embodiment.

FIG. 6 is a cross-sectional view cut along C-C in FIG. 5.

FIG. 7 is an end view illustrating an optical circuit element in the optical receiver according to the third embodiment.

FIG. 8 is a perspective view illustrating an optical receiver according to a fourth embodiment.

FIG. 9 is a perspective view illustrating an optical receiver according to a fifth embodiment.

FIG. 10 is a cross-sectional view cut along D-D in FIG. 9.

FIG. 11 is a perspective view illustrating an optical receiver according to a sixth embodiment.

### DESCRIPTION OF EMBODIMENTS

### First Embodiment

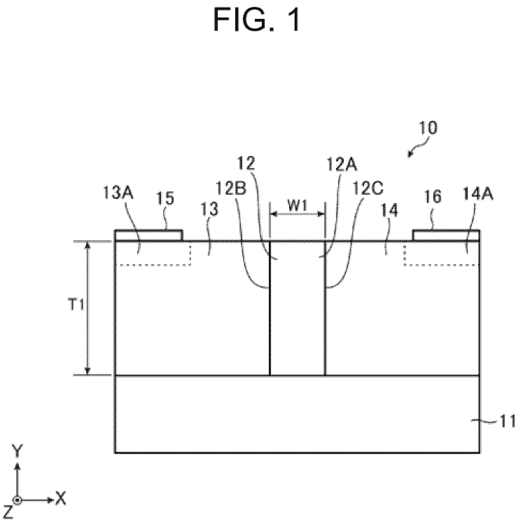

A waveguide-type light receiving element 10 according to a first embodiment will be described with reference to FIG. 1.

The waveguide-type light receiving element 10 according to the first embodiment is a lateral PIN type photodiode in which, on one main surface of a semi-insulating semiconductor substrate 11, a light absorbing layer 12 is formed, and an n-type semiconductor layer 13 and a p-type semiconductor layer 14 are formed with the light absorbing layer 12 interposed therebetween in a direction parallel to the one main surface of the semiconductor substrate 11, that is, in a so-called lateral direction of the semiconductor substrate 11, and which has a pn junction in the lateral direction.

In FIG. 1, a direction parallel to the one main surface of the semiconductor substrate 11 is defined as an X direction, a direction perpendicular to the one main surface of the semiconductor substrate 11 is defined as a Y direction, a direction orthogonal to the X direction and the Y direction is defined as a Z direction, and three dimensions are expressed by the X axis, the Y axis, and the Z axis.

The semiconductor substrate 11 is an indium phosphide (InP) substrate.

The light absorbing layer 12 is an i-type (intrinsic) semiconductor layer and is an undoped indium gallium arsenide (GaInAs) layer.

The n-type semiconductor layer 13 is an n-type indium phosphide (InP) layer.

The n-type semiconductor layer 13 is a cathode region.

The p-type semiconductor layer 14 is a p-type indium phosphide (InP) layer.

The p-type semiconductor layer 14 is an anode region.

The light absorbing layer 12 has a pair of joint surfaces 12B and 12C perpendicular to one main surface of the semiconductor substrate 11 and an incident end face 12A on which light is incident and which has facing end sides of the pair of joint surfaces as a pair of opposite sides.

The incident end face 12A has a rectangular shape.

The incident end face 12A has a layer thickness T1 longer than a layer width W1.

The incident end face 12A has a micron order layer thickness T1, which is 3 μm, or 3 μm or more.

The incident end face 12A has a submicron order layer width W1, which is less than 1 μm, for example, 0.6 μm.

Note that the layer thickness T1 is a thickness in the Y direction, and the layer width W1 is a width in the X direction. In addition, a length in the Z axis direction is a stripe length.

The n-type semiconductor layer 13 is formed on one main surface of the semiconductor substrate 11 on one side surface side of the light absorbing layer 12 by buried regrowth. That is, the n-type semiconductor layer 13 is formed on a left side surface side of the light absorbing layer 12 in the drawing.

The n-type semiconductor layer 13 is joined, that is, ni-joined, to one joint surface 12B of the pair of joint surfaces of the light absorbing layer 12.

The p-type semiconductor layer 14 is formed on the one main surface of the semiconductor substrate 11 on the other side surface side of the light absorbing layer 12 by buried regrowth. That is, the p-type semiconductor layer 14 is formed on a right side surface side of the light absorbing layer 12 in the drawing.

The p-type semiconductor layer 14 is joined, that is, pi-joined, to the other joint surface 12C of the pair of joint surfaces of the light absorbing layer 12.

A cathode electrode 15 is in ohmic contact with a surface of the n-type semiconductor layer 13.

If necessary, in order to strengthen the ohmic contact, the surface of the n-type semiconductor layer 13 located immediately below the cathode electrode 15 may be doped with an n-type impurity, thus forming a high-concentration n-type contact region 13A.

An anode electrode 16 is in ohmic contact with a surface of the p-type semiconductor layer 14.

If necessary, in order to strengthen the ohmic contact, the surface of the p-type semiconductor layer 14 located immediately below the anode electrode 16 may be doped with a p-type impurity, thus forming a high-concentration p-type contact region 14A.

Next, an operation of the waveguide-type light receiving element 10 according to the first embodiment will be described.

When an optical signal is incident on the incident end face 12A of the light absorbing layer 12 from a direction orthogonal to the incident end face 12A, that is, the Z direction, the incident optical signal is quickly absorbed by the light absorbing layer 12, and a free carrier corresponding to the incident optical signal is generated in the light absorbing layer 12.

The free carrier generated in the light absorbing layer 12 is extracted to the cathode electrode 15 by a reverse bias voltage applied between the cathode electrode 15 and the anode electrode 16, that is, a reverse bias voltage applied to a pin junction among the n-type semiconductor layer 13, the light absorbing layer 12, and the p-type semiconductor layer 14.

As a result, a current corresponding to the incident optical signal flows between the anode electrode 16 and the cathode electrode 15, and is detected as a photocurrent.

An operation speed in the waveguide-type light receiving element 10 is determined by a traveling time of a carrier flowing in a depletion layer.

Therefore, the operation speed in the waveguide-type light receiving element 10, that is, a so-called element response characteristic can be increased as extension of the depletion layer is narrower, in other words, as the layer width W1 of the light absorbing layer 12 in a direction in which the free carrier flows is shorter.

Since the light absorbing layer 12 in the waveguide-type light receiving element 10 according to the first embodiment has the submicron order layer width W1, which is, for example, less than 1 μm, the operation speed in the waveguide-type light receiving element 10 can be increased.

Furthermore, in a case where the incident end face 12A of the light absorbing layer 12 in the waveguide-type light receiving element 10 is butt-joint joined to an optical waveguide formed of a silicon layer having a general core thickness (layer thickness) of 0.22 μm in an optical circuit element, since the incident end face 12A has the micron order layer thickness T1, which is, for example, 3 μm or more, even when a center of the incident end face 12A and a center of the optical waveguide are shifted from design values by, for example, +1.5 μm in the Y direction which is a direction perpendicular to one main surface of the semiconductor substrate 11, all the optical signals in the Y direction from the optical waveguide are incident on the incident end face 12A.

That is, in the waveguide-type light receiving element 10, coupling tolerance in a direction perpendicular to one main surface of the semiconductor substrate 11 is relaxed with respect to mounting accuracy in the perpendicular direction.

Meanwhile, mounting accuracy in the X direction, which is a horizontal direction with respect to the one main surface of the semiconductor substrate 11, can be achieved with submicron accuracy by image recognition.

Therefore, even when the incident end face 12A has the submicron order layer width W1, which is, for example, less than 1 μm, there is no problem in coupling tolerance in the horizontal direction.

As described above, in the waveguide-type light receiving element 10 according to the first embodiment, the n-type semiconductor layer 13 and the p-type semiconductor layer 14 are formed with the light absorbing layer 12 interposed therebetween in a direction parallel to one main surface of the semiconductor substrate 11, that is, in a so-called lateral direction of the semiconductor substrate 11, a pn junction is formed in the lateral direction, and the incident end face 12A in the light absorbing layer 12 has a layer thickness T1 longer than a layer width W1. Therefore, the layer width W1 of the light absorbing layer 12 in a direction in which a free carrier flows is short, and therefore an operation speed in the waveguide-type light receiving element 10 can be increased.

Moreover, in the waveguide-type light receiving element 10 according to the first embodiment, in a case where the incident end face 12A is butt-joint joined to an optical waveguide in an optical circuit element, since the layer thickness T1 of the incident end face 12A in a perpendicular direction in which mounting accuracy is poorer than in a direction parallel to one main surface of the semiconductor substrate 11 is long, high coupling tolerance between the incident end face 12A and the optical waveguide in the optical circuit element can be obtained, and a high light receiving efficiency can be obtained.

In the waveguide-type light receiving element 10 according to the first embodiment, particularly, since the incident end face 12A has the micron order layer thickness T1, and the incident end face 12A has the submicron order layer width W1, it is possible to obtain favorable effects on an increase in operation speed, and high coupling tolerance in a case of butt-joint joining.

### Second Embodiment

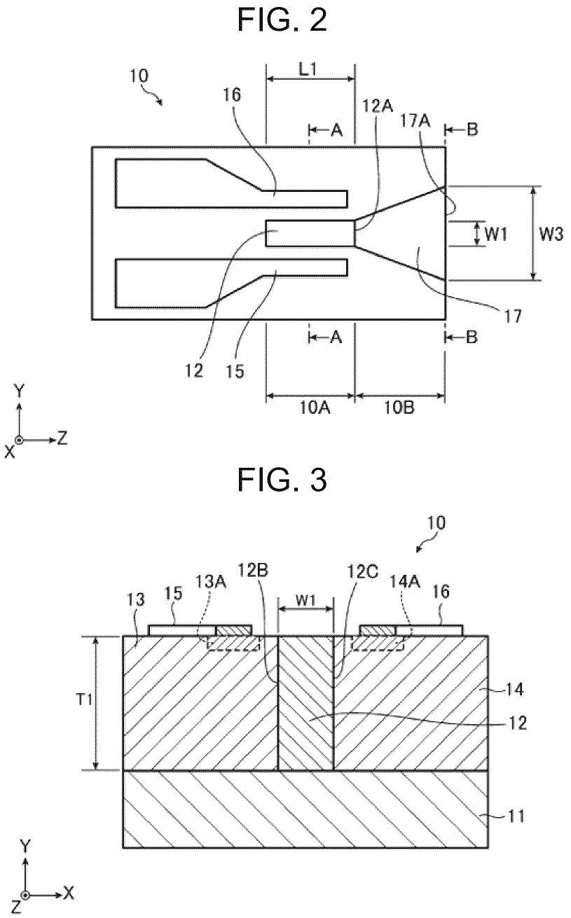

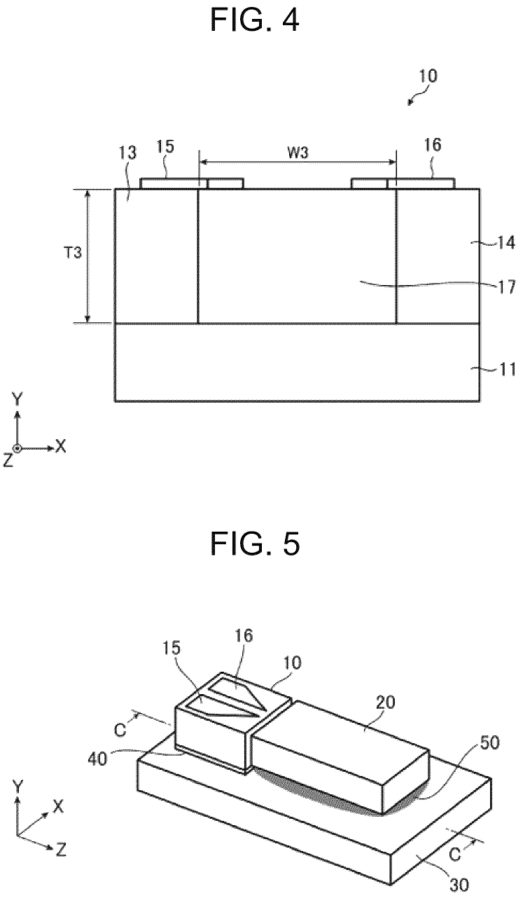

A waveguide-type light receiving element 10 according to a second embodiment will be described with reference to FIGS. 2 to 4.

In FIGS. 2 to 4, the same reference numerals as in FIG. 1 denote the same or corresponding portions.

The waveguide-type light receiving element 10 according to the second embodiment includes a semiconductor substrate 11, and a waveguide-type light receiving element section 10A and a light introducing section 10B formed on one main surface of the semiconductor substrate 11.

The waveguide-type light receiving element section 10A constitutes a lateral PIN type photodiode in which, on one main surface of the semi-insulating semiconductor substrate 11, a light absorbing layer 12 is formed, and an n-type semiconductor layer 13 and a p-type semiconductor layer 14 are formed with the light absorbing layer 12 interposed therebetween in a direction parallel to the one main surface of the semiconductor substrate 11, that is, in a so-called lateral direction of the semiconductor substrate 11, and which has a pn junction in the lateral direction.

The light absorbing layer 12 has a pair of joint surfaces 12B and 12C perpendicular to one main surface of the semiconductor substrate 11 and an incident end face 12A on which light is incident and which has facing end sides of the pair of joint surfaces as a pair of opposite sides.

The n-type semiconductor layer 13 has a cathode region joined to one of the pair of joint surfaces of the light absorbing layer 12.

The p-type semiconductor layer 14 has an anode region joined to the other of the pair of joint surfaces of the light absorbing layer 12.

The light introducing section 10B includes a light introducing path 17 having an introducing joint surface 17B joined to the incident end face 12A of the light absorbing layer 12 and a light introducing end face 17A on which light is incident and which is formed continuously from the introducing joint surface 17B in a tapered shape in such a manner that the light introducing end face 17A is parallel to one main surface of the semiconductor substrate 11 and gradually widens, that is, a size of the light introducing end face 17A in the Z direction gradually increases.

The light introducing end face 17A of the light introducing path 17 is joined to an emitting end face of an optical waveguide having a large mode diameter, such as an optical fiber, a planar lightwave circuit (PLC), a silicon nitride (SiN) waveguide, or a silicon (Si) waveguide that can obtain a large mode shape using a spot size converter in such a manner that the emitting end face faces the light introducing end face 17A in a close proximity manner.

That is, the light introducing end face 17A of the light introducing path 17 is butt-joint joined to the emitting end face of the optical waveguide having a large mode diameter.

Of course, the light introducing end face 17A of the light introducing path 17 may be butt-joint joined to an optical waveguide formed of a silicon layer having a general core thickness of 0.22 μm in an optical circuit element.

The semiconductor substrate 11 is an indium phosphide substrate.

The light absorbing layer 12 is an i-type semiconductor layer and is an undoped indium gallium arsenide layer.

The n-type semiconductor layer 13 is an n-type indium phosphide layer.

The p-type semiconductor layer 14 is a p-type indium phosphide layer.

The light introducing path 17 is a semiconductor layer having a band gap smaller than that of indium phosphide and larger than that of indium gallium arsenide.

The light introducing path 17 is an indium gallium arsenide phosphide (GaInAsP) layer.

An AlGaInAs layer may be used instead of the indium gallium arsenide phosphide (GaInAsP) layer.

Since the band gap of the light introducing path 17 is smaller than the band gap of each of the semiconductor substrate 11, the n-type semiconductor layer 13, and the p-type semiconductor layer 14 and larger than the band gap of the light absorbing layer 12, an optical signal incident on the light introducing end face 17A is propagated to the introducing joint surface 17B, that is, the incident end face 12A of the light absorbing layer 12.

The incident end face 12A of the light absorbing layer 12 has a rectangular shape.

The incident end face 12A has a layer thickness T1 longer than a layer width W1.

The incident end face 12A has a micron order layer thickness T1, which is 3 μm, or 3 μm or more.

The incident end face 12A has a submicron order layer width W1, which is less than 1 μm, for example, 0.6 μm.

Note that the layer thickness T1 is a thickness in the Y direction, and the layer width W1 is a width in the X direction. In addition, a length in the Z axis direction is a stripe length.

The n-type semiconductor layer 13 is formed on one main surface of the semiconductor substrate 11 on one side surface side of the light absorbing layer 12 by buried regrowth. That is, the n-type semiconductor layer 13 is formed on a left side surface side of the light absorbing layer 12 in the drawing.

The n-type semiconductor layer 13 is joined, that is, ni-joined, to one joint surface 12B of the pair of joint surfaces of the light absorbing layer 12.

The p-type semiconductor layer 14 is formed on the one main surface of the semiconductor substrate 11 on the other side surface side of the light absorbing layer 12 by buried regrowth. That is, the p-type semiconductor layer 14 is formed on a right side surface side of the light absorbing layer 12 in the drawing.

The p-type semiconductor layer 14 is joined, that is, pi-joined, to the other joint surface 12C of the pair of joint surfaces of the light absorbing layer 12.

A cathode electrode 15 is in ohmic contact with a surface of the n-type semiconductor layer 13.

If necessary, in order to strengthen the ohmic contact, the surface of the n-type semiconductor layer 13 located immediately below the cathode electrode 15 may be doped with an n-type impurity, thus forming a high-concentration n-type contact region 13A.

An anode electrode 16 is in ohmic contact with a surface of the p-type semiconductor layer 14.

If necessary, in order to strengthen the ohmic contact, the surface of the p-type semiconductor layer 14 located immediately below the anode electrode 16 may be doped with a p-type impurity, thus forming a high-concentration p-type contact region 14A.

The introducing joint surface 17B of the light introducing path 17 has the same shape as the incident end face 12A of the light absorbing layer 12, the layer thickness T1 is 3 μm, or 3 μm or more, and the layer width W1 is less than 1 μm, for example, 0.6 μm.

The light introducing end face 17A of the light introducing path 17 has a rectangular shape, and a central axis thereof coincides with a central axis of the introducing joint surface 17B.

A layer thickness T3 of the light introducing end face 17A is the same as the layer thickness T1 of the incident end face 12A.

A layer width W3 of the light introducing end face 17A is larger than the layer width W1 of the incident end face 12A.

The layer width W3 of the light introducing end face 17A is the same length as the layer thickness T1 of the incident end face 12A of the light absorbing layer 12.

That is, the light introducing end face 17A has a square shape.

Since the light introducing end face 17A has a square shape, an optical signal incident on the light introducing end face 17A can be propagated in the light introducing path 17 by a symmetrical circular mode shape.

In short, the light introducing path 17 has a shape in which the introducing joint surface 17B has a longitudinally long rectangular shape, the light introducing end face 17A has a square shape, an upper surface and a lower surface have the same trapezoidal shape, and a pair of side surfaces has a rectangular shape, and a layer thickness is constant.

Even when the light introducing path 17 is formed into a perfect circular mode shape by forming the light introducing end face 17A into a square shape, since the layer thickness is constant over the entire stripe length, it is easy to manufacture the light introducing path 17, which does not lead to a decrease in yield and an increase in cost.

Therefore, by setting the layer thickness T1 of the incident end face 12A, that is, the layer thickness T1 of the introducing joint surface 17B and the layer thickness T3 and the layer width W3 of the light introducing end face 17A in such a manner as to conform with an emitting end face of an optical waveguide having a large mode diameter, butt-joint joined to the light introducing end face 17A, coupling tolerance between the light introducing end face 17A and the emitting end face of the optical waveguide having a large mode diameter, that is, a coupling efficiency can be easily enhanced.

Next, an operation of the waveguide-type light receiving element 10 according to the second embodiment will be described.

When an optical signal is incident on the light introducing end face 17A of the light introducing path 17 in the light introducing section 10B from an emitting end face of an optical waveguide having a large mode diameter, the optical signal is propagated in the light introducing path 17, reaches the introducing joint surface 17B, and is incident on the incident end face 12A of the light absorbing layer 12 in the waveguide-type light receiving element section 10A.

The optical signal incident on the incident end face 12A of the light absorbing layer 12 is quickly absorbed by the light absorbing layer 12, and a free carrier corresponding to the incident optical signal is generated in the light absorbing layer 12.

The free carrier generated in the light absorbing layer 12 is extracted to the cathode electrode 15 by a reverse bias voltage applied between the cathode electrode 15 and the anode electrode 16, that is, a reverse bias voltage applied to a pin junction among the n-type semiconductor layer 13, the light absorbing layer 12, and the p-type semiconductor layer 14.

As a result, a current corresponding to the incident optical signal flows between the anode electrode 16 and the cathode electrode 15, and is detected as a photocurrent.

In the light introducing path 17, since the light introducing end face 17A of the light introducing path 17 has a micron order square shape, for example, a square shape of 3 μm, or 3 μm or more, an optical signal is propagated by a circular mode shape.

Moreover, coupling tolerance between the light introducing end face 17A and the light emitting end face of the optical waveguide having a large mode diameter, butt-joint joined to the light introducing end face 17A, that is, a coupling efficiency is enhanced.

Regarding an operation speed in the waveguide-type light receiving element section 10A, that is, a so-called element response characteristic, since the light absorbing layer 12 in the waveguide-type light receiving element section 10A has the submicron order layer width W1, which is, for example, less than 1 μm, the operation speed in the waveguide-type light receiving element section 10A can be increased.

As described above, in the waveguide-type light receiving element section 10A in the waveguide-type light receiving element 10 according to the first embodiment, the n-type semiconductor layer 13 and the p-type semiconductor layer 14 are formed with the light absorbing layer 12 interposed therebetween in a direction parallel to one main surface of the semiconductor substrate 11, that is, in a so-called lateral direction of the semiconductor substrate 11, and a pn junction is formed in the lateral direction, and the incident end face 12A in the light absorbing layer 12 has a layer thickness T1 longer than a layer width W1. Therefore, the layer width W1 of the light absorbing layer 12, which is a direction in which a free carrier flows, is shortened, and therefore an operation speed in the waveguide-type light receiving element section 10A can be increased.

Moreover, the light introducing section 10B in the waveguide-type light receiving element 10 according to the first embodiment includes the light introducing path 17 having the introducing joint surface 17B joined to the incident end face 12A of the light absorbing layer 12 and the light introducing end face 17A on which light is incident and which is formed continuously from the introducing joint surface 17B in a tapered shape in such a manner that the light introducing end face 17A is parallel to one main surface of the semiconductor substrate 11 and widens. Therefore, in a case where the light introducing end face 17A is butt-joint joined to an emitting end face of an optical waveguide having a large mode diameter, high coupling tolerance between the light introducing end face 17A and the emitting end face of the optical waveguide having a large mode diameter can be obtained, and a high light receiving efficiency can be obtained.

In the waveguide-type light receiving element 10 according to the second embodiment, particularly, since the incident end face 12A of the light absorbing layer 12 in the waveguide-type light receiving element section 10A has the micron order layer thickness T1, and the incident end face 12A has the submicron order layer width W1, an operation speed can be increased. In addition, since the light introducing end face 17A of the light introducing path 17 in the light introducing section 10B has the micron order layer thickness T3, which is the same as the layer thickness T1 of the incident end face 12A of the light absorbing layer 12, and the light introducing end face 17A also has the submicron order layer width W3, the light introducing path 17 can be easily manufactured, and moreover, a favorable effect on high coupling tolerance in a case of butt-joint joining can be obtained.

### Third Embodiment

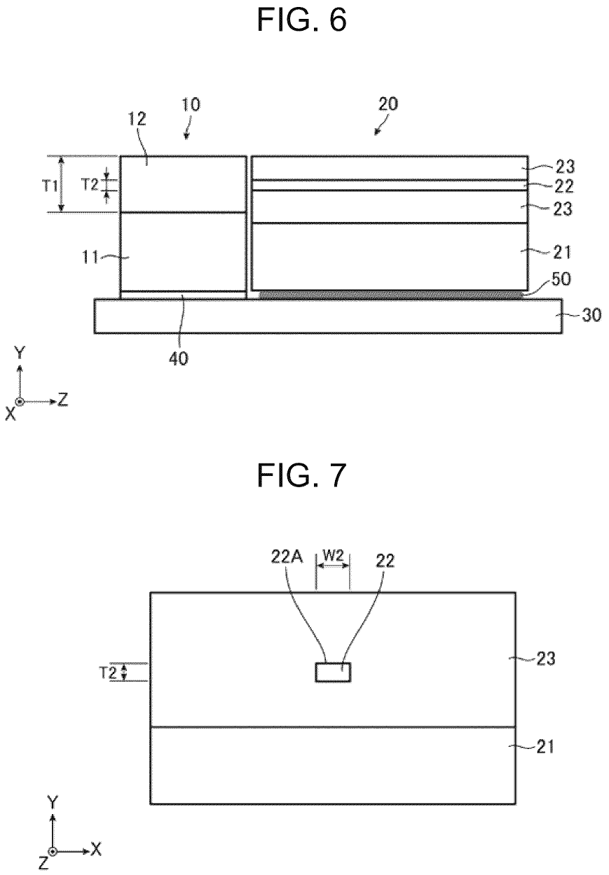

An optical receiver according to a third embodiment will be described with reference to FIGS. 5 to 7.

In FIGS. 5 to 7, the same reference numerals as in FIGS. 1 to 4 denote the same or corresponding portions.

The optical receiver according to the third embodiment includes, on a surface of a support base 30, a waveguide-type light receiving element 10 and an optical circuit element 20 butt-joint joined to each other.

The waveguide-type light receiving element 10 is the same as the waveguide-type light receiving element 10 according to the first embodiment.

Note that the waveguide-type light receiving element 10 may be the waveguide-type light receiving element 10 according to the second embodiment.

In the waveguide-type light receiving element 10, the other main surface of a semiconductor substrate 11 is fixed to the surface of the support base 30 with solder 40.

The optical circuit element 20 has an optical waveguide 22 formed of a silicon (Si) layer.

The optical circuit element 20 is constituted by a silicon on insulator (SOI) substrate, and has a structure in which the optical waveguide 22 formed of a silicon (Si) layer is embedded in a cladding layer 23 formed of silicon oxide (SiO₂) on one main surface of a silicon (Si) substrate 21.

In the optical circuit element 20, the other main surface of the silicon substrate 21 is fixed to the surface of the support base 30 with an adhesive 50.

The adhesive 50 is an adhesive of an ultraviolet curable resin. As the adhesive 50, a thermosetting resin or a thermoplastic resin may be used.

In the waveguide-type light receiving element 10 and the optical circuit element 20 fixed to the surface of the support base 30, a height from the surface of the support base 30 to an upper surface of the optical circuit element 20 is equal to a height from the surface of the support base 30 to an upper surface of the waveguide-type light receiving element 10.

The optical waveguide 22 has an emitting end face 22A that faces an incident end face 12A of the light absorbing layer 12 in the waveguide-type light receiving element 10 and emits light.

The emitting end face 22A has a rectangular shape.

A layer thickness T2 of the emitting end face 22A is 220 nm, which is a general thickness as a silicon layer of an SOI substrate. That is, the layer thickness T2 of the emitting end face 22A is the thickness of the silicon layer of the SOI substrate.

Note that the layer thickness T2 of the emitting end face 22A is not limited to 220 nm, and only needs to be equal to or larger than a thickness at which a propagation mode of a TE mode in optical signals in a 1.31 μm band and a 1.55 μm band can exist.

The optical circuit element 20 is constituted by an SOI substrate, and the optical waveguide 22 is formed of a silicon layer. However, a polymer layer, a silicon nitride SiN layer, silicon oxide (SiO₂), or the like may be used as the optical waveguide 22.

A layer width W2 of the emitting end face 22A is equal to or smaller than the layer width W1 of the incident end face 12A in the light absorbing layer 12 in the waveguide-type light receiving element 10.

A height from the other main surface of the silicon substrate 21 to a center of the emitting end face 22A in the optical waveguide 22 in the optical circuit element 20 is equal to a height from the other main surface of the semiconductor substrate 11 to a center of the incident end face 12A in the light absorbing layer 12 in the waveguide-type light receiving element 10.

The incident end face 12A of the light absorbing layer 12 in the waveguide-type light receiving element 10 and the emitting end face 22A of the optical waveguide 22 in the optical circuit element 20 are disposed in such a manner as to face each other, that is, butt-joint joined to each other, and the waveguide-type light receiving element 10 and the optical circuit element 20 are fixed to a surface of the support base 30.

The waveguide-type light receiving element 10 and the optical circuit element 20 are fixed to the surface of the support base 30 in such a manner that a center of the incident end face 12A in the light absorbing layer 12 in the waveguide-type light receiving element 10 and a center of the emitting end face 22A of the optical waveguide 22 in the optical circuit element 20 are on the same horizontal axis.

Note that, in a case where the waveguide-type light receiving element 10 according to the second embodiment is used as the waveguide-type light receiving element 10, the emitting end face 22A of the optical waveguide 22 in the optical circuit element 20 is disposed in such a manner as to face the incident end face 12A of the light absorbing layer 12 and the light introducing end face 17A of the light introducing path 17 in the waveguide-type light receiving element 10.

Next, an operation of the optical receiver according to the third embodiment will be described.

An optical signal propagated through the optical waveguide 22 in the optical circuit element 20 and emitted from the emitting end face 22A is incident on the incident end face 12A of the light absorbing layer 12 in the waveguide-type light receiving element 10.

Since an operation of the waveguide-type light receiving element 10 after the optical signal is incident on the incident end face 12A of the light absorbing layer 12 is the same as the operation of the waveguide-type light receiving element 10 according to the first embodiment, description thereof is omitted.

Next, a method for fixing the waveguide-type light receiving element 10 and the optical circuit element 20 to the surface of the support base 30 will be described.

First, the solder 40 is interposed between the other main surface of the semiconductor substrate 11 in the waveguide-type light receiving element 10 and the surface of the support base 30, and the waveguide-type light receiving element 10 is fixed to the support base 30 by the solder 40.

Thereafter, the adhesive 50 that is formed of an ultraviolet curable resin is applied to the other main surface of the silicon substrate 21 in the optical circuit element 20. Thereafter, the optical circuit element 20 is placed on the surface of the support base 30 in such a manner that the emitting end face 22A of the optical waveguide 22 in the optical circuit element 20 faces the incident end face 12A of the light absorbing layer 12 in the waveguide-type light receiving element 10 in a close proximity manner, and a center of the incident end face 12A and a center of the emitting end face 22A are aligned on the same horizontal axis.

After the optical circuit element 20 is aligned and placed on the surface of the support base 30, the adhesive 50 is cured by being irradiated with ultraviolet light, and the optical circuit element 20 is fixed to the support base 30 with the adhesive 50.

The alignment between the center of the incident end face 12A in the light absorbing layer 12 and the center of the emitting end face 22A in the optical waveguide 22 in the height direction, that is, in the Y direction is easy because a height from the other main surface of the silicon substrate 21 to a center of the emitting end face 22A in the optical waveguide 22 in the optical circuit element 20 is equal to a height from the other main surface of the semiconductor substrate 11 to a center of the incident end face 12A in the light absorbing layer 12 in the waveguide-type light receiving element 10.

In addition, alignment between the center of the incident end face 12A and the center of the emitting end face 22A in the lateral direction, that is, in the X direction can be performed with high accuracy by referring to a pattern on one main surface of the semiconductor substrate 11 in the waveguide-type light receiving element 10 and a pattern on one main surface of the silicon substrate 21 in the optical circuit element 20.

A reason why the adhesive 50 is used instead of solder for fixing the optical circuit element 20 to the support base 30 is as follows.

That is, the adhesive 50 has viscosity before being cured, it is easy to align the optical circuit element 20 with respect to the waveguide-type light receiving element 10, and by curing the adhesive 50 after the alignment, the optical circuit element 20 can be firmly fixed to the support base 30.

In the fixing with the adhesive 50, alignment is easy, and positional deviations due to center alignment and adhesion at the time of fixing are small.

Therefore, by fixing the optical circuit element 20 to the support base 30 with the adhesive 50 against a positional deviation generated in the thickness direction of the light absorbing layer 12 in the waveguide-type light receiving element 10 when the waveguide-type light receiving element 10 is fixed to the support base 30 with the solder 40, the height of the center of the light absorbing layer 12 in the waveguide-type light receiving element 10 and the height of the center of the optical waveguide 22 in the optical circuit element 20 can easily coincide with each other.

Therefore, when the layer thickness T1 of the incident end face 12A in the light absorbing layer 12 is 3 μm, favorable coupling can be obtained between the light absorbing layer 12 and the optical waveguide 22.

In the optical receiver according to the third embodiment configured as described above, since mounting accuracy in the X direction, which is a horizontal direction with respect to the surface of the support base 30, can be achieved with submicron accuracy by image recognition, there is no problem in coupling tolerance in the horizontal direction between the light absorbing layer 12 in the waveguide-type light receiving element 10 and the optical waveguide 22 in the optical circuit element 20.

Meanwhile, regarding mounting accuracy in the Y direction, which is a direction perpendicular to the surface of the support base 30, in a case where a step motor is used for alignment in the perpendicular direction due to a variation in the thickness of the semiconductor substrate 11 in the waveguide-type light receiving element 10, a variation in the thickness of the silicon substrate 21 in the optical circuit element 20, or a variation in the thickness of the solder 40, it is assumed that the center of the emitting end face 22A of the optical waveguide 22 is deviated from the center of the incident end face 12A of the light absorbing layer 12 by +0.3 μm in the height direction.

In addition, the following is also conceivable as a case where a deviation is generated in the height direction.

Conceivable are shrinkage caused by curing of the adhesive 50, volume change of the adhesive 50 caused by aging due to use of the optical receiver, and volume change of the adhesive 50 caused by change in environmental temperature in an environment in which the optical receiver is used.

Even in a case where a deviation is generated in the height direction as described above, since the incident end face 12A in the light absorbing layer 12 has the micron order layer thickness T1, which is, for example, 3 μm or more, even when the center of the emitting end face 22A in the optical waveguide 22 is deviated from the center of the incident end face 12A in the light absorbing layer 12 in the height direction by, for example, +1.5 μm, all the optical signals from the emitting end face 22A in the optical waveguide 22 are incident on the incident end face 12A in the light absorbing layer 12.

As a result, a light receiving efficiency from the emitting end face 22A of the optical waveguide 22 to the incident end face 12A of the light absorbing layer 12 does not decrease.

A reason why the incident end face 12A in the light absorbing layer 12 has the micron order layer thickness T1, which is 3 μm, or 3 μm or more, will be described.

After the optical circuit element 20 is fixed to the support base 30 with the adhesive 50, a main cause of generation of the deviation in the height direction is a change in volume due to thermal contraction or thermal expansion in the adhesive 50, that is, a change in thickness.

In a case of a general ultraviolet curable resin as the adhesive 50 used in this field, a linear expansion coefficient after curing is 100 ppm/K. Assuming that the thickness of the adhesive 50 when the optical circuit element 20 is fixed to the support base 30 is 200 μm and a temperature fluctuation range is +50° C., the thickness of the adhesive 50 is assumed to change in a range of +1.0 μm.

As a positional deviation in the height direction between the center of the emitting end face 22A in the optical waveguide 22 and the center of the incident end face 12A in the light absorbing layer 12, 1.3 μm obtained by adding mounting accuracy of ±0.3 μm in a case of using a step motor for alignment in the perpendicular direction is assumed.

In addition, the optical signal emitted from the emitting end face 22A of the optical waveguide 22 is defined to have a mode field radius of 0.2 μm of a base mode propagated through the optical waveguide 22.

Therefore, since the positional deviation is in a range of ±1.5 μm obtained by summing up a change in thickness of the adhesive 50 of ±1.0 μm, the mounting accuracy of ±0.3 μm, and the mode field radius of 0.2 μm, that is, since the layer thickness T1 of the incident end face 12A in the light absorbing layer 12 is 3 μm, or 3 μm or more, all the optical signals emitted from the emitting end face 22A in the optical waveguide 22 are incident on the incident end face 12A in the light absorbing layer 12.

As described above, the optical receiver according to the third embodiment includes the waveguide-type light receiving element 10 and the optical circuit element 20 butt-joint joined to each other on a surface of the support base 30, and in the waveguide-type light receiving element 10, the n-type semiconductor layer 13 and the p-type semiconductor layer 14 are formed with the light absorbing layer 12 interposed therebetween in a direction parallel to one main surface of the semiconductor substrate 11, that is, in a so-called lateral direction of the semiconductor substrate 11, a pn junction is formed in the lateral direction, the incident end face 12A in the light absorbing layer 12 has a layer thickness T1 longer than a layer width W1, and the optical circuit element 20 is fixed to a surface of the support base 30 in such a manner that the emitting end face 22A of the optical waveguide 22 in the optical circuit element 20 faces the incident end face 12A of the light absorbing layer 12. Therefore, it is possible to increase an operation speed in the waveguide-type light receiving element 10 on which an optical signal from the emitting end face 22A of the optical waveguide 22 is incident from the incident end face 12A.

Moreover, in the optical receiver according to the third embodiment, in the waveguide-type light receiving element 10, since the layer thickness T1 of the incident end face 12A in a perpendicular direction in which mounting accuracy in the optical circuit element 20 is poorer than in a direction parallel to the surface of the support base 30 is long, high coupling tolerance between the emitting end face 22A of the optical waveguide 22 and the incident end face 12A of the light absorbing layer 12 can be obtained, and a high light receiving efficiency can be obtained.

In the optical receiver according to the third embodiment, in the waveguide-type light receiving element 10, particularly, since the incident end face 12A has the micron order layer thickness T1 and the incident end face 12A has the submicron order layer width W1, it is possible to increase an operation speed in the waveguide-type light receiving element 10 on which an optical signal from the emitting end face 22A of the optical waveguide 22 is incident from the incident end face 12A, and to obtain a favorable effect on high coupling tolerance between the emitting end face 22A of the optical waveguide 22 and the incident end face 12A of the light absorbing layer 12.

### Fourth Embodiment

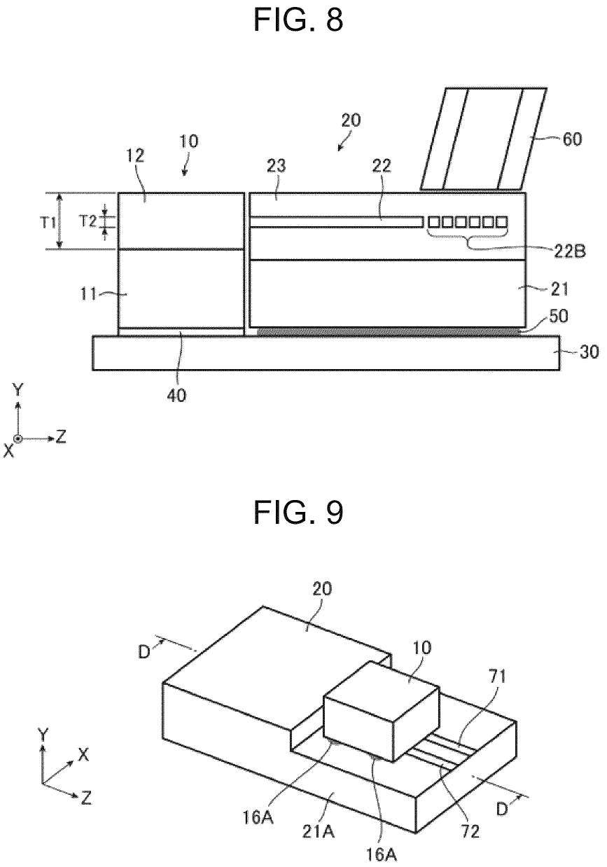

An optical receiver according to a fourth embodiment will be described with reference to FIG. 8.

In FIG. 8, the same reference numerals as in FIGS. 1 to 7 denote the same or corresponding portions.

The optical receiver according to the fourth embodiment is obtained by adding, to the optical receiver according to the third embodiment, an input port 22B that couples an optical signal from an optical fiber 60 to an optical waveguide 22 at an end of the optical waveguide 22 on a side opposite to an emitting end face 22A in an optical circuit element 20.

The optical receiver according to the fourth embodiment includes, on a surface of a support base 30, a waveguide-type light receiving element 10 and the optical circuit element 20 butt-joint joined to each other.

The waveguide-type light receiving element 10 is the same as the waveguide-type light receiving element 10 in the third embodiment, that is, the waveguide-type light receiving element 10 according to the first embodiment.

In the waveguide-type light receiving element 10, the other main surface of a semiconductor substrate 11 is fixed to the surface of the support base 30 with solder 40.

The optical circuit element 20 includes the optical waveguide 22 formed of a silicon layer and the input port 22B, and is substantially the same as the optical circuit element 20 in the third embodiment.

The optical waveguide 22 has an emitting end face 22A on one end face.

The input port 22B couples one end of the optical fiber 60 to the other end of the optical waveguide 22 on a side opposite to the emitting end face 22A.

The input port 22B propagates an optical signal emitted from the optical fiber 60 to the other end of the optical waveguide 22.

The input port 22B is a port by any of a surface coupling type coupling method using a surface diffraction grating (grating coupler), an end face coupling type coupling method using a spot size converter, and an evanescent coupling type coupling method.

FIG. 8 illustrates a surface coupling type using a grating coupler as the input port 22B, and illustrates a grating coupler portion which is a region in which a plurality of grooves is formed along the other end of the optical waveguide 22 on a surface layer of the other end of the optical waveguide 22.

The optical fiber 60 is fixed to the grating coupler portion.

Since an operation of the optical receiver according to the fourth embodiment is the same as the operation of the optical receiver according to the third embodiment, description thereof is omitted.

Next, fixing the waveguide-type light receiving element 10 and the optical circuit element 20 to a surface of the support base 30 will be described.

First, the solder 40 is interposed between the other main surface of the semiconductor substrate 11 in the waveguide-type light receiving element 10 and the surface of the support base 30, and the waveguide-type light receiving element 10 is fixed to the support base 30 by the solder 40.

Thereafter, an adhesive 50 that is formed of an ultraviolet curable resin is applied to the other main surface of a silicon substrate 21 in the optical circuit element 20. Thereafter, the optical circuit element 20 is disposed on the surface of the support base 30 in such a manner that the emitting end face 22A of the optical waveguide 22 in the optical circuit element 20 faces the incident end face 12A of the light absorbing layer 12 in the waveguide-type light receiving element 10 in a close proximity manner.

In this state, active center alignment is performed in which light is incident on the optical waveguide 22 from the optical fiber 60 via the input port 22B, the incident light is propagated through the optical waveguide 22 and is emitted from the emitting end face 22A to the incident end face 12A of the light absorbing layer 12, and a photocurrent detected by the waveguide-type light receiving element 10 is monitored.

When the center of the emitting end face 22A in the optical waveguide 22 coincides with the center of the incident end face 12A in the light absorbing layer 12 by active center alignment, the adhesive 50 is cured by being irradiated with ultraviolet light, and the optical circuit element 20 is fixed to the support base 30 with the adhesive 50.

As described above, the optical receiver according to the fourth embodiment has similar effects to those of the optical receiver according to the third embodiment. In addition, when the optical circuit element 20 is mounted on the support base 30, high coupling tolerance can be obtained between the light absorbing layer 12 in the waveguide-type light receiving element 10 and the optical waveguide 22 in the optical circuit element 20 by active center alignment, the optical waveguide 22 in the optical circuit element 20 can be surely aligned with a light receiving sensitivity peak position in the waveguide-type light receiving element 10, and a light receiving efficiency in the waveguide-type light receiving element 10 can be maximized.

### Fifth Embodiment

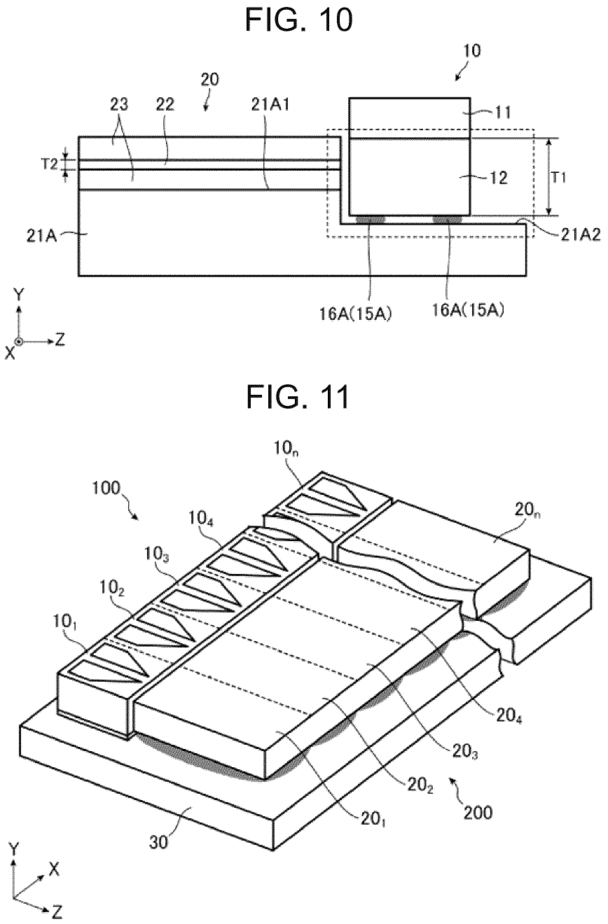

An optical receiver according to a fifth embodiment will be described with reference to FIGS. 9 and 10.

In FIGS. 9 and 10, the same reference numerals as in FIGS. 1 to 7 denote the same or corresponding portions.

The optical receiver according to the fifth embodiment includes a waveguide-type light receiving element 10 and an optical circuit element 20 butt-joint joined to each other.

The waveguide-type light receiving element 10 is a flip-chip mounted type waveguide-type light receiving element 10 basically having the same structure as the waveguide-type light receiving element 10 according to the first embodiment.

Note that the waveguide-type light receiving element 10 may be a flip-chip mounted type waveguide-type light receiving element 10 basically having the same structure as the waveguide-type light receiving element 10 according to the second embodiment.

Each of a cathode electrode 15A and an anode electrode 16A is constituted by a plurality of gold (Au) bump electrodes.

Note that each of the cathode electrode 15A and the anode electrode 16A may be constituted by a plurality of solder bump electrodes.

The cathode electrode 15A is connected to an n-type semiconductor layer.

The anode electrode 16A is connected to a p-type semiconductor layer.

In FIGS. 9 and 10, the cathode electrode 15A is not illustrated, but is located at a position facing the anode electrode 16A.

The optical circuit element 20 includes a semiconductor substrate 21A having an optical waveguide forming surface 21A1 and a light receiving element fixing surface 21A2 lower than the optical waveguide forming surface 21A1 on one main surface, an optical waveguide 22 formed on the optical waveguide forming surface 21A1 of the semiconductor substrate 20A and having an emitting end face 22A that emits light, and a cathode wiring layer 71 and an anode wiring layer 72 formed on the light receiving element fixing surface 21A2 of the semiconductor substrate 21A.

The cathode wiring layer 71 and the anode wiring layer 72 are high frequency lines that transmit an electric signal (output signal) obtained by photoelectrically converting an optical signal incident on the waveguide-type light receiving element 10.

The optical circuit element 20 is constituted by an SOI substrate, and has a structure in which, in an optical waveguide forming portion, the optical waveguide 22 formed of a silicon layer is embedded in a cladding layer 23 formed of silicon oxide on the optical waveguide forming surface 21A1 of the silicon substrate 21 which is a semiconductor substrate.

The light receiving element fixing surface 21A2 is obtained by forming a dug portion by performing an etching treatment on a position where the waveguide-type light receiving element 10 is mounted on the semiconductor substrate 21A.

A height from the light receiving element fixing surface 21A2 to a center of the emitting end face 22A in the optical waveguide 22 in the optical circuit element 20 is equal to a height from a contact surface or a contact point in the cathode electrode 15A and the anode electrode 16A in the waveguide-type light receiving element 10 to a center of the incident end face 12A in the light absorbing layer 12.

The waveguide-type light receiving element 10 is disposed on the light receiving element fixing surface 21A2 of the semiconductor substrate 21A with the semiconductor substrate 11 on an upper side and the cathode electrode 15A and the anode electrode 16A on a lower side, and the cathode electrode 15A and the anode electrode 16A are electrically connected and fixed to the cathode wiring layer 71 and the anode wiring layer 72 with solder, respectively, whereby the waveguide-type light receiving element 10 is fixed to the light receiving element fixing surface 21A2 of the semiconductor substrate 21A.

That is, the waveguide-type light receiving element 10 is flip-chip mounted on the light receiving element fixing surface 21A2 of the semiconductor substrate 21A while the other main surface of the semiconductor substrate 11 is an upper surface.

In short, the incident end face 12A of the light absorbing layer 12 faces the emitting end face 22A of the optical waveguide 22, the cathode electrode 15A is connected to the cathode wiring layer 71, the anode electrode 16A is connected to the anode wiring layer 72, a center of the incident end face 12A of the light absorbing layer 12 and a center of the emitting end face 22A of the optical waveguide 22 are aligned with each other, and the waveguide-type light receiving element 10 is fixed to the light receiving element fixing surface 21A2 of the semiconductor substrate 21A.

Note that, in a case where the waveguide-type light receiving element 10 according to the second embodiment is used as the waveguide-type light receiving element 10, the emitting end face 22A of the optical waveguide 22 in the optical circuit element 20 is disposed in such a manner as to face the light introducing end face 17A of the light introducing path 17 in the waveguide-type light receiving element 10.

Since an operation of the optical receiver according to the fifth embodiment is substantially the same as the operation of the optical receiver according to the third embodiment, description thereof is omitted.

Next, a method for fixing the waveguide-type light receiving element 10 to the light receiving element fixing surface 21A2 of the semiconductor substrate 21A in the optical circuit element 20 will be described.

While the semiconductor substrate 11 in the waveguide-type light receiving element 10 is on an upper side and the cathode electrode 15A and the anode electrode 16A are on a lower side, the waveguide-type light receiving element 10 is disposed on the light receiving element fixing surface 21A2 of the semiconductor substrate 21A in the optical circuit element 20 in such a manner that the incident end face 12A of the light absorbing layer 12 in the waveguide-type light receiving element 10 faces the emitting end face 22A of the optical waveguide 22 in the optical circuit element 20 in a close proximity manner.

Then, alignment is performed by a generally known mechanical method in such a manner that a center of the incident end face 12A is on the same horizontal axis as a center of the emitting end face 22A.

The alignment between the center of the incident end face 12A in the light absorbing layer 12 and the center of the emitting end face 22A in the optical waveguide 22 in the height direction, that is, in the Y direction is easy because a height from a contact surface or a contact point in the cathode electrode 15A and the anode electrode 16A in the waveguide-type light receiving element 10 to a center of the incident end face 12A in the light absorbing layer 12 is equal to a height from the light receiving element fixing surface 21A2 in the optical circuit element 20 to a center of the emitting end face 22A in the optical waveguide 22.

In addition, alignment between the center of the incident end face 12A and the center of the emitting end face 22A in the lateral direction, that is, in the X direction can be performed with high accuracy by referring to a pattern on one main surface of the semiconductor substrate 11 in the waveguide-type light receiving element 10 and a pattern on one main surface of the silicon substrate 21 in the optical circuit element 20.

In this state, the cathode electrode 15A and the anode electrode 16A in the waveguide-type light receiving element 10 are fixed to the cathode wiring layer 71 and the anode wiring layer 72 with solder, respectively.

As a result, the cathode electrode 15A and the anode electrode 16A are electrically connected to the cathode wiring layer 71 and the anode wiring layer 72, respectively.

In addition, the waveguide-type light receiving element 10 is fixed to the light receiving element fixing surface 21A2 of the semiconductor substrate 21A in the optical circuit element 20.

In the optical receiver according to the fifth embodiment configured as described above, since mounting accuracy in the X direction, which is a horizontal direction with respect to the light receiving element fixing surface 21A2 of the semiconductor substrate 21A in the optical circuit element 20, can be achieved with submicron accuracy by image recognition, there is no problem in coupling tolerance in the horizontal direction between the light absorbing layer 12 in the waveguide-type light receiving element 10 and the optical waveguide 22 in the optical circuit element 20.

Meanwhile, by flip-chip mounting the waveguide-type light receiving element 10 on the light receiving element fixing surface 21A2 of the semiconductor substrate 21A, there is no influence of variations in the thickness of the semiconductor substrate 11 in the waveguide-type light receiving element 10 and the thickness of the semiconductor substrate 21A in the optical circuit element 20. Therefore, the position of the center of the incident end face 12A in the light absorbing layer 12 and the center of the emitting end face 22A in the optical waveguide 22 in a height direction, that is, in the Y direction mechanically coincide with each other easily.

The mounting accuracy in the Y direction, which is a direction perpendicular to the light receiving element fixing surface 21A2 of the semiconductor substrate 21A, is assumed as follows.

That is, the height of each of the cathode electrode 15A and the anode electrode 16A is about 15 μm, and a thickness tolerance is assumed to be about +10%, that is, about +1.5 μm.

Since the incident end face 12A in the waveguide-type light receiving element 10 has the micron order layer thickness T1, which is, for example, 3 μm or more, even when the center of the incident end face 12A in the light absorbing layer 12 is deviated from the center of the emitting end face 22A in the optical waveguide 22 in the height direction by, for example, +1.5 μm, all the optical signals from the emitting end face 22A in the optical waveguide 22 are incident on the incident end face 12A in the light absorbing layer 12.

As a result, a light receiving efficiency from the emitting end face 22A of the optical waveguide 22 to the incident end face 12A of the light absorbing layer 12 does not decrease.

As described above, in the optical receiver according to the fifth embodiment, the waveguide-type light receiving element 10 butt-joint joined to the optical circuit element 20 is flip-chip mounted on the light receiving element fixing surface 21A2 of the semiconductor substrate 21A in the optical circuit element 20, and in the waveguide-type light receiving element 10, the n-type semiconductor layer 13 and the p-type semiconductor layer 14 are formed with the light absorbing layer 12 interposed therebetween in a direction parallel to one main surface of the semiconductor substrate 11, that is, in a so-called lateral direction of the semiconductor substrate 11, a pn junction is formed in the lateral direction, the incident end face 12A in the light absorbing layer 12 has a layer thickness T1 longer than a layer width W1, and the optical circuit element 20 is fixed to a surface of the support base 30 in such a manner that the emitting end face 22A of the optical waveguide 22 in the optical circuit element 20 faces the incident end face 12A of the light absorbing layer 12. Therefore, it is possible to increase an operation speed in the waveguide-type light receiving element 10 on which an optical signal from the emitting end face 22A of the optical waveguide 22 is incident from the incident end face 12A.

Moreover, in the optical receiver according to the fifth embodiment, since the waveguide-type light receiving element 10 is flip-chip mounted on the light receiving element fixing surface 21A2 of the semiconductor substrate 21A in the optical circuit element 20, and the layer thickness T1 of the incident end face 12A is long, high coupling tolerance between the emitting end face 22A of the optical waveguide 22 and the incident end face 12A of the light absorbing layer 12 can be obtained even in a direction parallel to the light receiving element fixing surface 21A2, and a high light receiving efficiency can be obtained.

In the optical receiver according to the fifth embodiment, in the waveguide-type light receiving element 10, particularly, since the incident end face 12A has the micron order layer thickness T1 and the incident end face 12A has the submicron order layer width W1, it is possible to increase an operation speed in the waveguide-type light receiving element 10 on which an optical signal from the emitting end face 22A of the optical waveguide 22 is incident from the incident end face 12A, and to obtain a favorable effect on high coupling tolerance between the emitting end face 22A of the optical waveguide 22 and the incident end face 12A of the light absorbing layer 12.

### Sixth Embodiment

An optical receiver according to a sixth embodiment will be described with reference to FIG. 11.

In FIG. 11, the same reference numerals as in FIGS. 1 to 10 denote the same or corresponding portions.

The optical receiver according to the sixth embodiment is obtained by arranging a plurality of optical receivers selected from the optical receivers according to the third to fifth embodiments in an array in a direction along a pin junction, that is, in the X direction which is a lateral direction, in a waveguide-type light receiving element 10 on one main surface of a semiconductor substrate 11.

The optical receiver according to the sixth embodiment includes: a light receiving element array 100 in which a plurality of waveguide-type light receiving element sections 10₁ to 10ₙ is arranged on a straight line in the lateral direction on one main surface of the semi-insulating semiconductor substrate 11, that is, arranged in an array; and an optical waveguide array 200 in which a plurality of circuit element sections 20₁ to 20ₙ is arranged on a straight line on one main surface of a semiconductor substrate 21A which is a silicon substrate, that is, arranged in an array.

Note that “n” is a total number of 2 or more.

In a case where each of the waveguide-type light receiving element sections 10₁ to 10ₙ is the waveguide-type light receiving element 10 according to the first embodiment, each of the waveguide-type light receiving element sections 10₁ to 10ₙ includes a light absorbing layer 12, an n-type semiconductor layer 13 and a p-type semiconductor layer 14 with the light absorbing layer 12 interposed therebetween in the lateral direction of the semiconductor substrate 11, a cathode electrode 15, and an anode electrode 16, formed on one main surface of a common semiconductor substrate 11

In a case where each of the circuit element sections 20₁ to 20ₙ is the optical circuit element 20 in the optical receiver according to the third embodiment, each of the circuit element sections 20₁ to 20ₙ has an optical waveguide 22 formed of a silicon layer and a silicon oxide cladding layer 23 embedding the optical waveguide 22, formed on one main surface of the common semiconductor substrate 21A.

An incident end face 12A of the light absorbing layer 12 in each of the waveguide-type light receiving element sections 10₁ to 10ₙ and an emitting end face 22A of the optical waveguide 22 in each of the circuit element sections 20₁ to 20ₙ are aligned with each other in such a manner that corresponding end faces face each other in a close proximity manner and a center of the incident end face 12A and a center of the emitting end face 22A corresponding to each other are on the same horizontal axis, the other main surface of the semiconductor substrate 11 in the light receiving element array 100 is fixed to a surface of the support base 30 with solder, and the other main surface of the semiconductor substrate 21A in the optical waveguide array 200 is fixed with an adhesive.

That is, the incident end face 12A of the light absorbing layer 12 and the emitting end face 22A of the optical waveguide 22 corresponding to each other are butt-joint joined to each other, and the light receiving element array 100 and the optical waveguide array 200 are fixed to the surface of the support base 30.

As described in the fifth embodiment, in a case where each of the cathode electrode 15 and the anode electrode 16 is formed of a plurality of bump electrodes and a flip-chip mounted type is used, the common semiconductor substrate 21A has the optical waveguide forming surface 21A1 and the light receiving element fixing surface 21A2 lower than the optical waveguide forming surface 21A1, the plurality of circuit element sections 20₁ to 20ₙ is formed on the optical waveguide forming surface 21A1 of the common semiconductor substrate 21A, and the light receiving element array 100 is placed and fixed, that is, flip-chip mounted, on the light receiving element fixing surface 21A2 of the common semiconductor substrate 21A.

In the light receiving element array 100, when the plurality of waveguide-type light receiving element sections 10₁ to 10ₙ is formed on one main surface of the common semiconductor substrate 11, there is a case where the light receiving element array 100 is inclined from the waveguide-type light receiving element section 10₁ toward the waveguide-type light receiving element section 10ₙ with respect to one main surface of the common semiconductor substrate 11 in a substrate thinning step, and heights from the one main surface of the semiconductor substrate 11 to the centers of the incident end faces 12A of the light absorbing layers 12 in the plurality of waveguide-type light receiving element sections 10₁ to 10ₙ are different from each other.

In addition, in a case where the light receiving element array 100 is fixed to the surface of the support base 30 with solder, there is a case where the light receiving element array 100 is inclined in a direction orthogonal to the arrangement direction of the plurality of waveguide-type light receiving element sections 10₁ to 10ₙ on a horizontal plane parallel to the surface of the support base 30, that is, in the Z direction, and a height from the surface of the support base 30 to the center of the incident end face 12A of the light absorbing layer 12 in each of the plurality of waveguide-type light receiving element sections 10₁ to 10ₙ is different from a set value.

Furthermore, in a case where the optical waveguide array 200 is fixed to the surface of the support base 30 with an adhesive, there is a case where a height from the surface of the support base 30 to the center of the emitting end face 22A of the optical waveguide 22 in each of the plurality of circuit element sections 20₁ to 20ₙ is deviated due to shrinkage caused by curing of the adhesive, volume change of the adhesive caused by aging due to use of the optical receiver, volume change of the adhesive caused by change in environmental temperature in an environment in which the optical receiver is used, and the like.

Furthermore, in a case where each of the cathode electrode 15 and the anode electrode 16 is a bump electrode and a flip-chip mounted type is used, there is a case where heights from the light receiving element fixing surface 21A2 of the common semiconductor substrate 21A to the centers of the incident end faces 12A of the light absorbing layers 12 in the plurality of waveguide-type light receiving element sections 10₁ to 10ₙ are different from each other due to a thickness tolerance caused by the bump electrodes and solder.

Even in a case where a deviation in the height to the center of the incident end face 12A of the light absorbing layer 12 in each of the plurality of waveguide-type light receiving element sections 10₁ to 10ₙ or a deviation in the height to the center of the emitting end face 22A of the optical waveguide 22 in each of the plurality of circuit element sections 20₁ to 20ₙ is generated, since the incident end face 12A of the light absorbing layer 12 in each of the waveguide-type light receiving element sections 10₁ to 10ₙ, has a layer thickness T1 longer than a layer width W1, in each of the waveguide-type light receiving element sections 10₁ to 10ₙ, coupling tolerance in a direction perpendicular to one main surface of the semiconductor substrate 11 is relaxed with respect to mounting accuracy in the perpendicular direction, high coupling tolerance between the incident end face 12A of the light absorbing layer 12 in each of the waveguide-type light receiving element sections 10₁ to 10ₙ and the emitting end face 22A of the optical waveguide 22 in each of the circuit element sections 20₁ to 20ₙ, corresponding to each other, can be obtained, and a high light receiving efficiency can be obtained.

Note that each of the waveguide-type light receiving element sections 10₁ to 10ₙ may be the waveguide-type light receiving element 10 according to the second embodiment. In this case, each of the waveguide-type light receiving element sections 10₁ to 10ₙ includes a waveguide-type light receiving element section 10A, a light introducing section 10B, a cathode electrode 15, and an anode electrode 16. The waveguide-type light receiving element section 10A includes a light absorbing layer 12, and an n-type semiconductor layer 13 and a p-type semiconductor layer 14 with the light absorbing layer 12 interposed therebetween in a lateral direction of a semiconductor substrate 11 on one main surface of the semiconductor substrate 11. The light introducing section 10B includes a light introducing path 17 having an introducing joint surface 17B and a light introducing end face 17A and gradually widening from the introducing joint surface 17B toward the light introducing end face 17A.

As described above, in the optical receiver according to the sixth embodiment, the layer width W1 of the incident end face 12A of the light absorbing layer 12 in each of the waveguide-type light receiving element sections 10₁ to 10ₙ is short, and an operation speed in each of the waveguide-type light receiving element sections 10₁ to 10ₙ can be increased.

Moreover, since the incident end face 12A of the light absorbing layer 12 in each of the waveguide-type light receiving element sections 10₁ to 10ₙ has a layer thickness T1 longer than a layer width W1, high coupling tolerance between the incident end face 12A of the light absorbing layer 12 in each of the waveguide-type light receiving element sections 10₁ to 10ₙ and the emitting end face 22A of the optical waveguide 22 in each of the circuit element sections 20₁ to 20ₙ, corresponding to each other can be obtained, and a high light receiving efficiency can be obtained.

In the optical receiver according to the sixth embodiment, in each of the waveguide-type light receiving element sections 10₁ to 10ₙ, particularly, since the incident end face 12A has the micron order layer thickness T1 and the incident end face 12A has the submicron order layer width W1, it is possible to increase an operation speed in the waveguide-type light receiving element 10 on which an optical signal from the emitting end face 22A of the optical waveguide 22 is incident from the incident end face 12A, and to obtain a favorable effect on high coupling tolerance between the emitting end face 22A of the optical waveguide 22 and the incident end face 12A of the light absorbing layer 12.

Note that the embodiments can be freely combined to each other, any constituent element in each of the embodiments can be modified, or any constituent element in each of the embodiments can be omitted.

### INDUSTRIAL APPLICABILITY

The optical receiver according to the present disclosure are suitable as high-sensitivity light receivers in fields of optical communication, optical information processing, and the like.

### REFERENCE SIGNS LIST

10: Waveguide-type light receiving element, 10A and 10₁ to 10ₙ: Waveguide-type light receiving element section, 10B: Light introducing section, 11: Semiconductor substrate, 12: Light absorbing layer, 12A: Incident end face, 13: N-type semiconductor layer, 14: P-type semiconductor layer, 15 and 15A: Cathode electrode, 16 and 16A: Anode electrode, 17: Light introducing path, 17A: Light introducing end face, 17B: Introducing joint surface, 20: Optical circuit element, 20₁ to 20ₙ: Circuit element section, 21 and 21A: Semiconductor substrate, 21A1: Optical waveguide forming surface, 21A2: Light receiving element fixing surface, 22: Optical waveguide, 22A: Emitting end face, 23: Cladding layer, 30: Support base, 40: Solder, 50: Adhesive, 60: Optical fiber, 70A: Cathode wiring layer, 70B: Anode wiring layer, 100: Light receiving element array, 200: Optical waveguide array

1. An optical receiver comprising:
a support base; a waveguide-type light receiving element fixed to a surface of the support base; and an optical circuit element fixed to the surface of the support base, wherein the waveguide-type light receiving element includes:
a semi-insulating semiconductor substrate;
a light absorbing layer that is formed on one main surface of the semiconductor substrate and has a pair of joint surfaces perpendicular to the one main surface of the semiconductor substrate and an incident end face on which light is incident and which has facing end sides of the pair of joint surfaces as a pair of opposite sides, the incident end face having a layer thickness longer than a layer width;
an n-type semiconductor layer joined to one of the pair of joint surfaces of the light absorbing layer on the one main surface of the semiconductor substrate; and
a p-type semiconductor layer joined to the other of the pair of joint surfaces of the light absorbing layer on the one main surface of the semiconductor substrate, and
the optical circuit element includes an optical waveguide having an emitting end face to emit light, the emitting end face facing the incident end face of the light absorbing layer in the waveguide-type light receiving element.

2. An optical receiver comprising: a support base; a waveguide-type light receiving element fixed to a surface of the support base; and an optical circuit element fixed to the surface of the support base,
wherein the waveguide-type light receiving element includes: a semi-insulating semiconductor substrate; and a waveguide-type light receiving element section and a light introducing section, formed on one main surface of the semiconductor substrate, wherein
the waveguide-type light receiving element section includes: a light absorbing layer that is formed on the one main surface of the semiconductor substrate and has a pair of joint surfaces perpendicular to the one main surface of the semiconductor substrate and an incident end face on which light is incident and which has facing end sides of the pair of joint surfaces as a pair of opposite sides, the incident end face having a layer thickness longer than a layer width; an n-type semiconductor layer joined to one of the pair of joint surfaces of the light absorbing layer on the one main surface of the semiconductor substrate; and a p-type semiconductor layer joined to the other of the pair of joint surfaces of the light absorbing layer on the one main surface of the semiconductor substrate,
the light introducing section includes a light introducing path having: an introducing joint surface joined to the incident end face of the light absorbing layer; and a light introducing end face on which light is incident and which is formed continuously from the introducing joint surface in a tapered shape in such a manner that the light introducing end face is parallel to the one main surface of the semiconductor substrate and gradually widens, and
the optical circuit element includes an optical waveguide having an emitting end face to emit light, the emitting end face facing the incident end face of the light absorbing layer in the waveguide-type light receiving element.

3. An optical receiver comprising: a waveguide-type light receiving element; and an optical circuit element,
wherein the optical circuit element includes: a semiconductor substrate having an optical waveguide forming surface and a light receiving element fixing surface lower than the optical waveguide forming surface on one main surface; an optical waveguide formed on the optical waveguide forming surface of the semiconductor substrate and having an emitting end face to emit light; and a cathode wiring layer and an anode wiring layer, formed on the light receiving element fixing surface of the semiconductor substrate,
the waveguide-type light receiving element includes: a semi-insulating semiconductor substrate; a light absorbing layer that is formed on one main surface of the semi-insulating semiconductor substrate and has a pair of joint surfaces perpendicular to the one main surface of the semi-insulating semiconductor substrate and an incident end face on which light is incident and which has facing end sides of the pair of joint surfaces as a pair of opposite sides, the incident end face having a layer thickness longer than a layer width; an n-type semiconductor layer joined to one of the pair of joint surfaces of the light absorbing layer on the one main surface of the semi-insulating semiconductor substrate; and a p-type semiconductor layer joined to the other of the pair of joint surfaces of the light absorbing layer on the one main surface of the semi-insulating semiconductor substrate, and
the waveguide-type light receiving element is fixed to the light receiving element fixing surface of the semiconductor substrate in the optical circuit element while the incident end face of the light absorbing layer faces the emitting end face of the optical waveguide in the optical circuit element, a cathode electrode is connected to the cathode wiring layer in the optical circuit element, and an anode electrode is connected to the anode wiring layer in the optical circuit element.

4. An optical receiver comprising: a waveguide-type light receiving element; and an optical circuit element,
wherein the optical circuit element includes: a semiconductor substrate having an optical waveguide forming surface and a light receiving element fixing surface lower than the optical waveguide forming surface on one main surface; an optical waveguide formed on the optical waveguide forming surface of the semiconductor substrate and having an emitting end face to emit light; and a cathode wiring layer and an anode wiring layer, formed on the light receiving element fixing surface of the semiconductor substrate,
the waveguide-type light receiving element includes: a semi-insulating semiconductor substrate; and a waveguide-type light receiving element section and a light introducing section, formed on one main surface of the semi-insulating semiconductor substrate,
the waveguide-type light receiving element section includes: a light absorbing layer that is formed on the one main surface of the semi-insulating semiconductor substrate and has a pair of joint surfaces perpendicular to the one main surface of the semi-insulating semiconductor substrate and an incident end face on which light is incident and which has facing end sides of the pair of joint surfaces as a pair of opposite sides, the incident end face having a layer thickness longer than a layer width; an n-type semiconductor layer joined to one of the pair of joint surfaces of the light absorbing layer on the one main surface of the semi-insulating semiconductor substrate; and a p-type semiconductor layer joined to the other of the pair of joint surfaces of the light absorbing layer on the one main surface of the semi-insulating semiconductor substrate,
the light introducing section includes: a light introducing path having an introducing joint surface joined to the incident end face of the light absorbing layer; and a light introducing end face on which light is incident and which is formed continuously from the introducing joint surface in a tapered shape in such a manner that the light introducing end face is parallel to the one main surface of the semi-insulating semiconductor substrate and gradually widens, and
the waveguide-type light receiving element is fixed to the light receiving element fixing surface of the semiconductor substrate in the optical circuit element while the incident end face of the light absorbing layer faces the emitting end face of the optical waveguide in the optical circuit element, a cathode electrode is connected to the cathode wiring layer in the optical circuit element, and an anode electrode is connected to the anode wiring layer in the optical circuit element.

5. The optical receiver according to claim 1, wherein
the semiconductor substrate in the waveguide-type light receiving element is an indium phosphide (InP) substrate,
the light absorbing layer in the waveguide-type light receiving element is an undoped indium gallium arsenide (GaInAs) layer,
the n-type semiconductor layer in the waveguide-type light receiving element is an n-type indium phosphide (InP) layer, and
the p-type semiconductor layer in the waveguide-type light receiving element is a p-type indium phosphide (InP) layer.

6. The optical receiver according to claim 1, wherein
the incident end face of the light absorbing layer in the waveguide-type light receiving element has a micron order layer thickness, and
the incident end face of the light absorbing layer in the waveguide-type light receiving element has a submicron order layer width.

7. The optical receiver according to claim 1, wherein
the incident end face of the light absorbing layer in the waveguide-type light receiving element has a layer thickness of 3 μm or more, and
the incident end face of the light absorbing layer in the waveguide-type light receiving element has a layer width of less than 1 μm.

8. The optical receiver according to claim 6, which further comprising:
a cathode electrode constituted by a bump electrode connected to the n-type semiconductor layer in the waveguide-type light receiving element; and
an anode electrode constituted by a bump electrode connected to the p-type semiconductor layer in the waveguide-type light receiving element.

9. The optical receiver according to claim 2, wherein
the semiconductor substrate in the waveguide-type light receiving element is an indium phosphide (InP) substrate,
the light absorbing layer in the waveguide-type light receiving element is an undoped indium gallium arsenide (GaInAs) layer,
the n-type semiconductor layer in the waveguide-type light receiving element is an n-type indium phosphide (InP) layer,
the p-type semiconductor layer in the waveguide-type light receiving element is a p-type indium phosphide (InP) layer, and
the light introducing path of the light introducing section in the waveguide-type light receiving element is a semiconductor layer having a band gap smaller than that of indium phosphide and larger than that of indium gallium arsenide.

10. The optical receiver according to claim 2, wherein
the incident end face of the light absorbing layer in the waveguide-type light receiving element has a micron order layer thickness,
the incident end face of the light absorbing layer in the waveguide-type light receiving element has a submicron order layer width, and
the light introducing end face of the light introducing path in the waveguide-type light receiving element has a micron order layer thickness and a micron order layer width.

11. The optical receiver according to claim 2, wherein
the incident end face of the light absorbing layer has a layer thickness of 3 μm or more, and the incident end face of the light absorbing layer has a layer width of less than 1 μm, and
the light introducing end face of the light introducing path has a layer thickness and a layer width equal to the layer thickness of the incident end face of the light absorbing layer.

12. The optical receiver according to claim 1, wherein the optical waveguide in the optical circuit element is formed of a silicon layer on one main surface of a silicon substrate.

13. The optical receiver according to claim 12, wherein
the waveguide-type light receiving element is fixed to the surface of the support base with solder between the other main surface of the semiconductor substrate in the waveguide-type light receiving element and the surface of the support base, and
the optical circuit element is fixed to the surface of the support base with an adhesive between the other main surface of the silicon substrate in the optical circuit element and the surface of the support base.

14. The optical receiver according to claim 12, wherein a height from the other main surface of the semiconductor substrate to a center of the incident end face in the light absorbing layer in the waveguide-type light receiving element is equal to a height from the other main surface of the silicon substrate to a center of the emitting end face in the optical waveguide in the optical circuit element.

15. The optical receiver according to claim 12, wherein the optical circuit element further includes an input port to couple an optical signal from an optical fiber to the optical waveguide at an end of the optical waveguide on a side opposite to the emitting end face.

16. The optical receiver according to claim 15, wherein the input port is a port by any of a surface coupling type coupling method using a surface diffraction grating, an end face coupling type coupling method using a spot size converter, and an evanescent coupling type coupling method.

17. The optical receiver according to claim 3, wherein the semiconductor substrate of the optical circuit element is a silicon substrate, and the optical waveguide is a silicon layer.

18. An optical receiver comprising a light receiving element array and an optical waveguide array, wherein
the light receiving element array includes a common semi-insulating semiconductor substrate and a plurality of waveguide-type light receiving element sections arranged on a straight line in a lateral direction on one main surface of the common semi-insulating semiconductor substrate,
each of the plurality of waveguide-type light receiving element sections includes an n-type semiconductor layer, a light absorbing layer, and a p-type semiconductor layer sequentially formed in a lateral direction on the one main surface of the common semi-insulating semiconductor substrate, and an incident end face on which light is incident in the light absorbing layer has a layer thickness longer than a layer width, and
the optical waveguide array includes a common semiconductor substrate and a plurality of optical waveguides arranged on a straight line in a lateral direction on the one main surface of the common semiconductor substrate, each of the optical waveguides having an emitting end face to emit light, the emitting end face facing and being butt-joint joined to the incident end face of the light absorbing layer in each of the plurality of waveguide-type light receiving element sections,
the common semi-insulating semiconductor substrate in the light receiving element array is an indium phosphide (InP) substrate,
the light absorbing layer of each of the plurality of waveguide-type light receiving element sections is an undoped indium gallium arsenide (GaInAs) layer,
the n-type semiconductor layer of each of the plurality of waveguide-type light receiving element sections is an n-type indium phosphide (InP) layer,
the p-type semiconductor layer of each of the plurality of waveguide-type light receiving element sections is a p-type indium phosphide (InP) layer,
the common semiconductor substrate of the optical waveguide array is a silicon substrate, and
the plurality of optical waveguides are silicon layers.

19. The optical receiver according to claim 18, wherein
the incident end face of the light absorbing layer in each of the plurality of waveguide-type light receiving element sections has a layer thickness of 3 μm or more, and the incident end face of the light absorbing layer has a layer width of less than 1 μm.

20. The optical receiver according to claim 19, wherein
a cathode electrode to which the n-type semiconductor layer of each of the plurality of waveguide-type light receiving element sections is connected is a bump electrode,
an anode electrode to which the p-type semiconductor layer of each of the plurality of waveguide-type light receiving element sections is connected is a bump electrode,
the common semiconductor substrate of the optical waveguide array has an optical waveguide forming surface and a light receiving element fixing surface lower than the optical waveguide forming surface on the one main surface,
a plurality of optical waveguides of the optical waveguide array is formed on the optical waveguide forming surface, and
the light receiving element array is flip-chip mounted on the light receiving element fixing surface.
